(19) United States
(12) Patent Application Publication
(10) Pub. No.: US 2011/0068390 A1
(43) Pub. Date: Mar. 24, 2011

(54) SEMICONDUCTOR DEVICE AND METHOD FOR MANUFACTURING SAME

(75) Inventor: Masaaki OGASAWARA, Hyogo-ken (JP)

(73) Assignee: Kabushiki Kaisha Toshiba, Tokyo (JP)

(21) Appl. No.: 12/884,126

(22) Filed: Sep. 16, 2010

(30) Foreign Application Priority Data
Sep. 24, 2009 (JP) 2009-218560

(51) Int. Cl. H01L 29/78; H01L 21/336

(52) U.S. Cl. 257/330; 438/270; 257/E29.262; 257/E21.409

(57) ABSTRACT

According to one embodiment, a semiconductor device includes a semiconductor substrate, a drain layer provided thereon, a first body layer provided thereon, source layers and a gate electrode buried in each of a plurality of trenches. The source layers are discretely arranged in a staggered pattern on a surface of the first body layer in a first direction and in a second direction orthogonal to the first direction. The trenches extend in a third direction on the surface of the first body layer, are arranged in a fourth direction orthogonal to the third direction, and pierce through the source layer and the first body layer into the drain layer. The gate electrode is buried in each of the trenches via a gate insulating film. Sum of the width of the source layer and the spacing between the source layer and the adjacent source layer is smaller than spacing between the adjacent trenches.

### CROSS-REFERENCE TO RELATED APPLICATIONS

This application is based upon and claims the benefit of priority from the prior Japanese Patent Application No. 2009-218560, filed on Sep. 24, 2009; the entire contents of which are incorporated herein by reference.

### FIELD

Embodiments described herein relate generally to a semiconductor device and a method for manufacturing the same.

### BACKGROUND

Numerous products of power MOS transistors and IGBTs (insulated gate bipolar transistors) are developed as trench type devices, which can achieve lower ON resistance, faster speed, and smaller cell pitch. In a power MOS transistor having a trench gate structure, in view of ensuring the output breakdown voltage and decreasing the ON resistance, it is known that trench gates are shaped in a protrusion/depression configuration, with N source layers and P⁺ body layers arranged in a staggered pattern (see, e.g., JP-A 2009-76738 (Kokai)).

In the trench power MOS transistor described in JP-A 2009-76738 (Kokai), miniaturization of transistor features results in smaller mask alignment margin, making it difficult to ensure the output breakdown voltage. Furthermore, the yield may decrease if there is no mask alignment margin.

### BRIEF DESCRIPTION OF THE DRAWINGS

FIG. 1 is a plan view showing a trench power MOS transistor according to a first embodiment of the invention;

FIG. 2 is a cross-sectional view of the trench power MOS transistor taken along line A-A in FIG. 1;

FIG. 3 is a cross-sectional view of the trench power MOS transistor taken along line B-B in FIG. 1;

FIGS. 4A and 4B show the flow of carriers generated at breakdown of the trench power MOS transistor according to the first embodiment of the invention;

FIGS. 5 to 8 are cross-sectional views showing a process for manufacturing the trench power MOS transistor according to the first embodiment of the invention;

FIG. 9 is a plan view of a trench power MOS transistor with the N source layers and the P⁺ body layers rotated according to the first embodiment of the invention;

FIG. 10 is a plan view of a trench power MOS transistor with circular P⁺ body layers arranged therein according to the first embodiment of the invention;

FIG. 11 is a plan view of a trench power MOS transistor with rectangular P⁺ body layers arranged therein with an irregular pitch according to the first embodiment of the invention;

FIG. 12 is a plan view of a trench power MOS transistor with striped P⁺ body layers added thereto according to the first embodiment of the invention;

FIG. 13 is a plan view showing a trench power MOS transistor according to a second embodiment of the invention;

FIG. 14 shows formation of an inversion layer in the trench power MOS transistor taken along line C-C in FIG. 13;

FIG. 15 is a plan view of a trench power MOS transistor with the P⁺ body layers rotated according to a second embodiment of the invention; and

FIG. 16 is a plan view showing a trench power MOS transistor according to a third embodiment of the invention.

### DETAILED DESCRIPTION

In general, according to one embodiment, a semiconductor device includes a semiconductor substrate of a first conductivity type, a drain layer of the first conductivity type, a first body layer of a second conductivity type, a plurality of source layers of the first conductivity type and a gate electrode buried in each of a plurality of trenches. The drain layer of the first conductivity type is provided on the semiconductor substrate. The first body layer of a second conductivity type is provided on a surface of the drain layer. The plurality of source layers of the first conductivity type are discretely arranged on a surface of the first body layer in a staggered pattern with a first spacing in a first direction and a second spacing in a second direction orthogonal to the first direction, and each of the source layers has a first width in the first direction and a second width in the second direction. The plurality of trenches extend in a third direction on the surface of the first body layer, are arranged in a fourth direction orthogonal to the third direction, and pierce through the source layer and the first body layer into the drain layer. The gate electrode is buried in each of the trenches via a gate insulating film provided at bottom and on a side surface of the each of the trenches. Sum of the width of the source layer and the spacing between the source layer and the adjacent source layer is smaller than spacing between the adjacent trenches.

Embodiments of the invention will now be described with reference to the drawings.

### First Embodiment

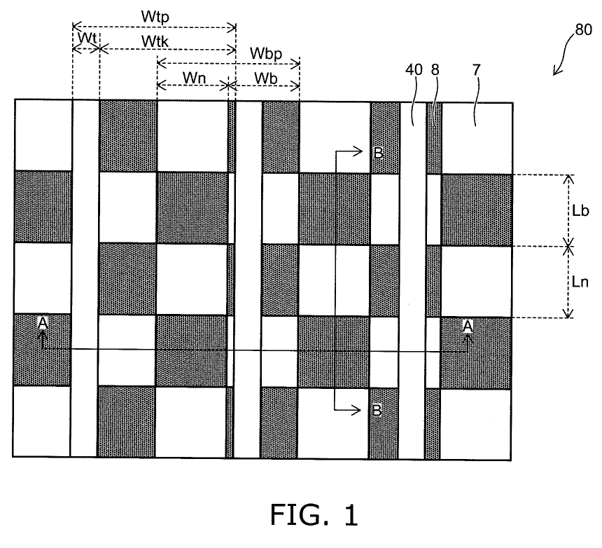

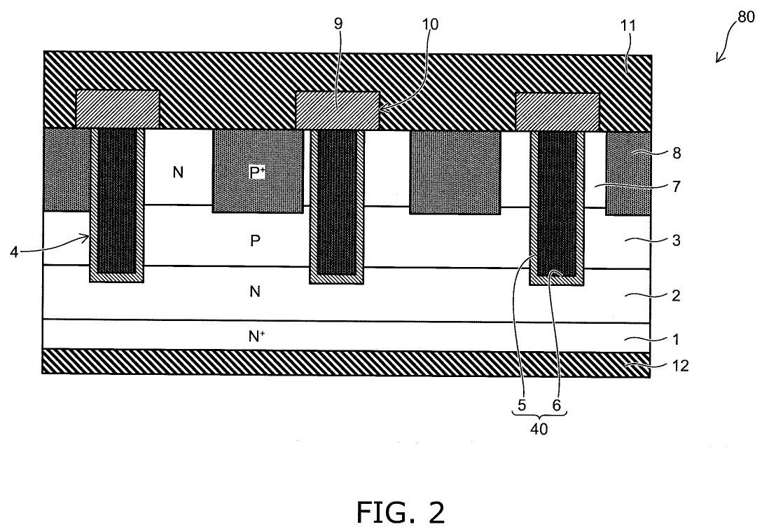

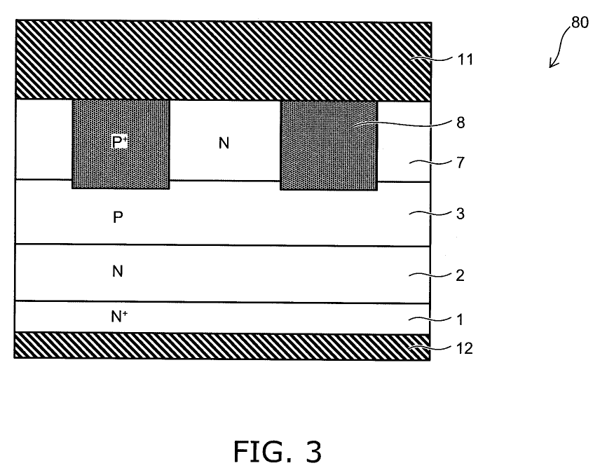

First, a semiconductor device and a method for manufacturing the same according to a first embodiment of the invention are described with reference to the drawings. FIG. 1 is a plan view showing a trench power MOS transistor. FIG. 2 is a cross-sectional view of the trench power MOS transistor taken along line A-A in FIG. 1. FIG. 3 is a cross-sectional view of the trench power MOS transistor taken along line B-B in FIG. 1. In this embodiment, N source layers and P⁺ body layers are arranged in a staggered pattern so that the sum of the width of the N source layer and the width of the P³⁺ body layer is smaller than the spacing between the trench gates.

As shown in FIG. 1, the trench power MOS transistor 80 is a silicon Nch MOS transistor having a trench gate structure. The trench power MOS transistor 80 includes a plurality of trench gates 40 juxtaposed in the figure in a vertically striped pattern. The trench gates 40 have a width of trench width Wt, a spacing of trench spacing Wtk, and a pitch of trench pitch Wtp (Wtp=Wt+Wtk).

The N source layers 7 and the P⁺ body layers 8 are shaped like rectangles and arranged perpendicular to the trench gate 40 (horizontally in the figure) in a staggered pattern. The P⁺ body layer 8 has a horizontal dimension of P⁺ body layer dimension Wb, a vertical dimension of P⁺ body layer dimension Lb, and a horizontal pitch of P⁺ body layer pitch Wbp. The N source layer 7 has a horizontal dimension of N source layer dimension Wn and a vertical dimension of N source layer dimension Ln. The N source layers 7 and the P⁺ body layers 8 are divided by the trench gate 40, and are not provided immediately below the trench gate 40.

Here, the relationship among the P⁺ body layer pitch Wbp, the P⁺ body layer dimension Wb, and the N source layer dimension Wn is set as follows.

Wbp=Wb+Wn (1)

The relationship among the P⁺ body layer pitch Wbp, the trench spacing Wtk, and the trench pitch Wtp is set as follows.

Wbp<Wtk<Wtp (2)

Thus, by these settings, two types of regions occur between the trench gates 40 arranged horizontally. One type of region includes a P⁺ body layer 8, an N source layer 7, and a P⁺ body layer 8. The other type of region includes an N source layer 7, a P⁺ body layer 8, and an N source layer 7. Furthermore, the N source layer 7 in contact with the trench gate 40 is in contact with the P⁺ body layer 8 located contiguously and horizontally in the figure. The N source layer 7 in contact with the trench gate 40 is in contact with the P⁺ body layer 8 located contiguously thereabove in the figure. The N source layer 7 in contact with the trench gate 40 is in contact with the P⁺ body layer 8 located contiguously therebelow in the figure.

Here, the trench gates 40 are formed in a striped pattern. However, alternatively, the trench gates 40 may be formed in a mesh pattern.

As shown in FIG. 2, the trench power MOS transistor 80 includes an N drain layer 2 on the first major surface (front surface) of an N⁺ silicon substrate 1. A P body layer 3 is provided on the first major surface (front surface) of the N drain layer 2. The N source layers 7 and the P⁺ body layers 8 are arranged contiguously on the first major surface (front surface) of the P body layer 3.

Trench grooves 4 are provided so as to penetrate through the N source layer 7, the P⁺ body layer 8, and the P body layer 3 to the N drain layer 2. The trench groove 4 is buried with a trench gate 40 composed of a gate insulating film 5 and a gate electrode film 6. An insulating film 9 as an interlayer insulating film is provided on the N source layer 7, the P⁺ body layer 8, and the trench gate 40. The insulating film 9 between the regions above the trench gates 40 is selectively etched to provide an opening 10. A source electrode 11 is provided on the insulating film 9 and the opening 10 so as to cover the opening 10. A drain electrode 12 is provided on the second major surface (rear surface) of the N⁺ silicon substrate 1 opposite to the first major surface (front surface).

As shown in FIG. 3, the trench power MOS transistor 80 includes an N drain layer 2 on the first major surface (front surface) of an N⁺ silicon substrate 1. A P body layer 3 is provided on the first major surface (front surface) of the N drain layer 2. The N source layers 7 and the P⁺ body layers 8 are arranged contiguously on the first major surface (front surface) of the P body layer 3. A source electrode 11 is provided on the N source layers 7 and the P⁺ body layers 8. A drain electrode 12 is provided on the second major surface (rear surface) of the N⁺ silicon substrate 1 opposite to the first major surface (front surface).

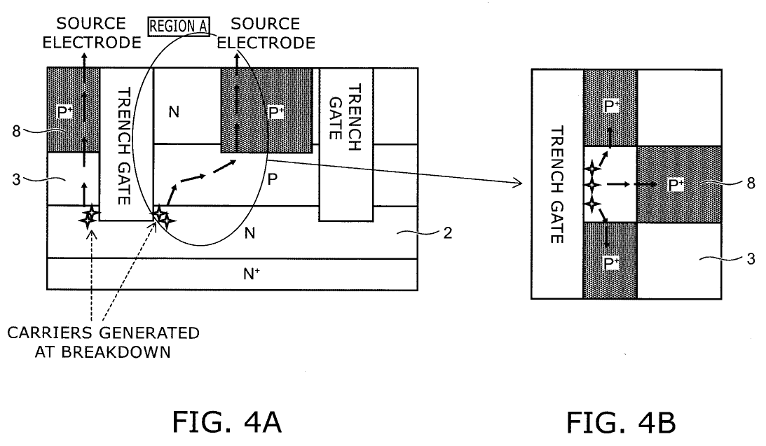

Next, the output breakdown voltage of the trench power MOS transistor is described with reference to FIGS. 4A and 4B. FIGS. 4A and 4B show the flow of carriers generated at breakdown of the trench power MOS transistor. More specifically, FIG. 4A is a cross-sectional view showing the flow of carriers. FIG. 4B is a plan view of region A in FIG. 4A.

As shown in FIG. 4A, when the drain side of the trench power MOS transistor 80 is applied with a high voltage, the junction between the N drain layer 2 and the P body layer 3 undergoes breakdown, generating carriers at the bottom of the side surface of the trench gate 40 (in the N drain layer 2 near the junction).

Carriers on the P⁺ body layer 8 side flow vertically from the P body layer 3 through the P⁺ body layer 8 to the source electrode 11, and are ejected from the source.

On the other hand, as shown in FIGS. 4A and 4B, carriers on the N source layer 7 side flow horizontally from the P body layer 3 to the P⁺ body layers 8 (to the three neighboring P⁺ body layers 8), then flow vertically from the P⁺ body layer 8 to the source electrode 11, and are ejected from the source.

Thus, carriers generated at breakdown are rapidly ejected from the source irrespective of either on the P⁺ body layer 8 side or on the N source layer 7 side. Hence, the operation of the parasitic npn bipolar transistor (where the N drain layer 2 is a collector, the P body layer 3 is a base, and the N source layer 7 is an emitter) can be significantly suppressed. Therefore, the decrease of output breakdown voltage (avalanche withstand capability) is suppressed, and a high output breakdown voltage (avalanche withstand capability) can be ensured. Furthermore, the N source layers 7 and the P⁺ body layers 8 are formed in a staggered pattern without using an alignment mark (described later in detail). Hence, miniaturization of features does not result in the yield decrease of the trench power MOS transistor 80.

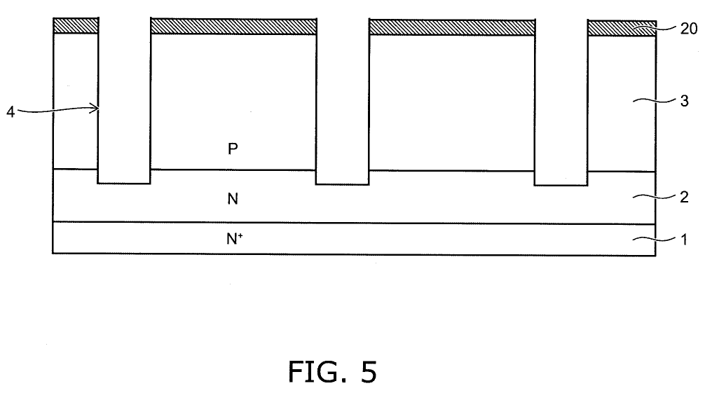

Next, a method for manufacturing a trench power MOS transistor is described with reference to FIGS. 5 to 8. FIGS. 5 to 8 are cross-sectional views showing a process for manufacturing a trench power MOS transistor.

As shown in FIG. 5, first, on an N⁺ silicon substrate 1 uniformly doped with N-type impurity at a high concentration (e.g., 3×10¹⁹/cm³), an N drain layer 2 doped with N-type impurity at a relatively low concentration is formed by silicon epitaxial growth (e.g., epitaxial thickness 3.5 μm). Here, in the epitaxial growth, it is desirable to use a condition of relatively low temperature in which auto-doping of the high-concentration impurity in the N⁺ silicon substrate 1 is less likely to occur.

After the N drain layer 2 is formed, the surface of the N drain layer 2 is subjected to boron ion implantation (e.g., acceleration voltage 400 eV and dose amount 8×10¹²/cm²) and high-temperature heat treatment. Thus, a P body layer 3 containing P-type impurity at a relatively low concentration is formed on the N drain layer 2. Here, the ion implantation is performed using a resist film, not shown, as a mask.

After the P body layer 3 is formed, a mask material 20 (e.g., silicon nitride (Si₃N₄) film) is formed on the P body layer 3. The mask material 20 is selectively etched by e.g. RIE (reactive ion etching) using a resist film, not shown, as a mask.

After the resist film is removed, the mask material 20 is used as a mask to form trench grooves 4 (e.g., with a trench width Wt of 0.18 μm) by e.g. RIE so as to penetrate through the P body layer 3 and expose the upper portion of the N drain layer 2. The RIE is followed by a RIE damage recovery process, and the trench grooves 4 are cleaned.

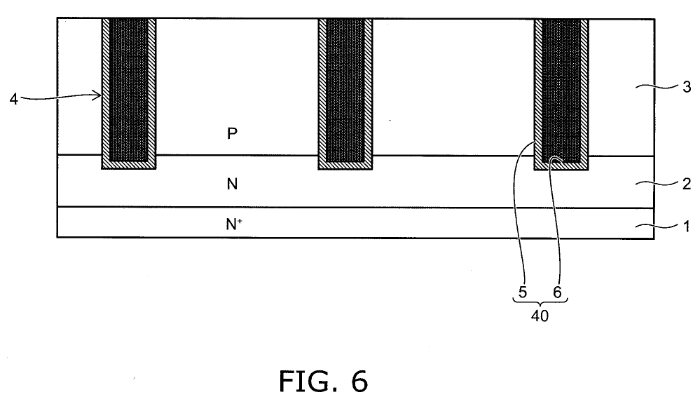

Next, as shown in FIG. 6, a gate insulating film 5 is formed by thermal oxidation. An undoped polycrystalline silicon film is deposited on the gate insulating film 5 so as to fill the trench groove 4. The undoped polycrystalline silicon film is subjected to ion implantation of N-type impurity and high-temperature heat treatment to form an N⁺ polycrystalline silicon film. The N⁺ polycrystalline silicon film, the mask material 20, and the gate insulating film 5 are planarized so that the P body layer 3 is exposed. Thus, a trench gate 40 is formed in the trench groove 4. Here, an undoped polycrystalline silicon film is deposited. However, alternatively, an N⁺ polycrystalline silicon film doped with N-type impurity at a high concentration may be deposited.

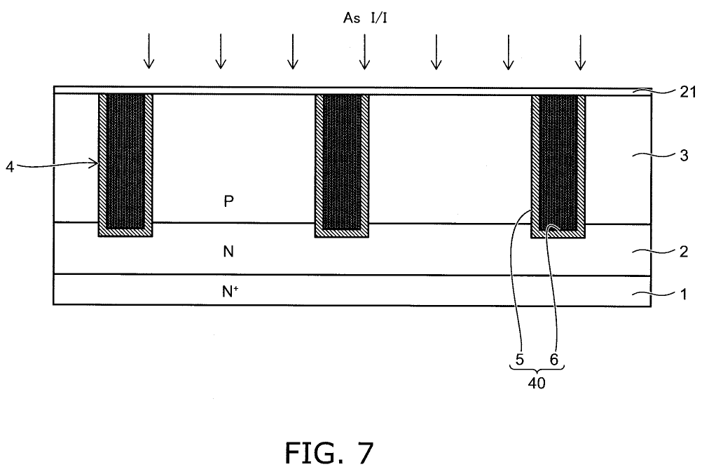

Subsequently, as shown in FIG. 7, a silicon oxide film 21 having a relatively thin film thickness is formed by thermal oxidation. N-type impurity is ion-implanted into the entire surface of the P body layer 3 through the silicon oxide film 21. In this ion implantation, for instance, As (arsenic) ions are implanted with an acceleration voltage of 65 eV and a dose amount of 3×10¹⁵/cm².

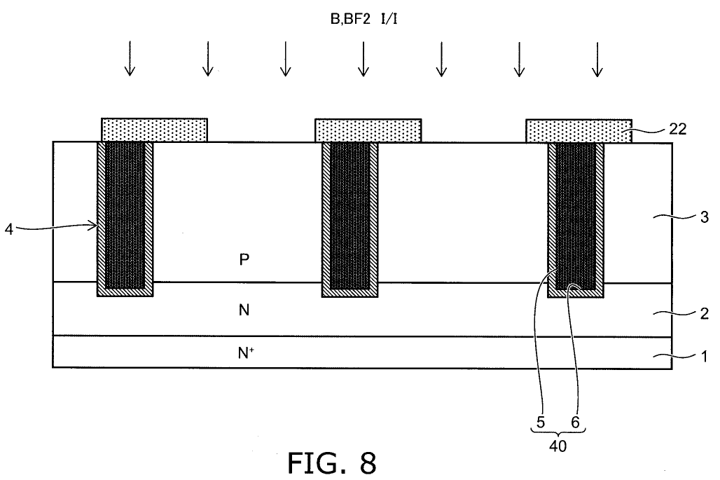

Then, as shown in FIG. 8, after the silicon oxide film 21 is removed, a resist film 22 is formed. The pitch of the resist film 22 is equal to the P⁺ body layer pitch Wbp. Using the resist film 22 as a mask, P-type impurity is ion-implanted into the surface of the P body layer 3. In this ion implantation, for instance, boron ions are implanted under three conditions: an acceleration voltage of 220 eV and a dose amount of 3×10¹²/cm²; an acceleration voltage of 100 eV and a dose amount of 2×10¹⁴/cm²; and an acceleration voltage of 55 eV and a dose amount of 6×10¹⁵/cm². Furthermore, BF₂ is implanted with an acceleration voltage of 40 eV and a dose amount of 3×10¹⁵/cm².

This resist film 22 is formed similarly to the initial exposure step (first exposure) without using an alignment mark. That is, the alignment mark of the mask is not aligned with the fiducial mark formed on the wafer surface. Hence, the positional relationship between the trench gate 40 and the P⁺ body layer 8 is not established with high accuracy.

After the resist film 22 is removed, high-temperature heat treatment is performed. Thus, the N-type ion-implanted layer is activated to form an N source layer 7, and the P-type ion-implanted layer is activated to form a P⁺ body layer 8. The N-type ion-implanted layer in the region ion-implanted with P-type impurity has a relatively low concentration. Hence, this region constitutes a P⁺ body layer 8.

The formation of the N source layers 7 and the P⁺ body layers 8 in a staggered pattern is followed by known processes for forming interlayer insulating films, openings, and electrodes. Thus, the trench power MOS transistor 80 is completed.

In this example, the P⁺ body layers 8 of the trench power MOS transistor 80 are regularly arranged in a staggered pattern perpendicular to the striped trench gates. However, the trench power MOS transistor may be configured differently.

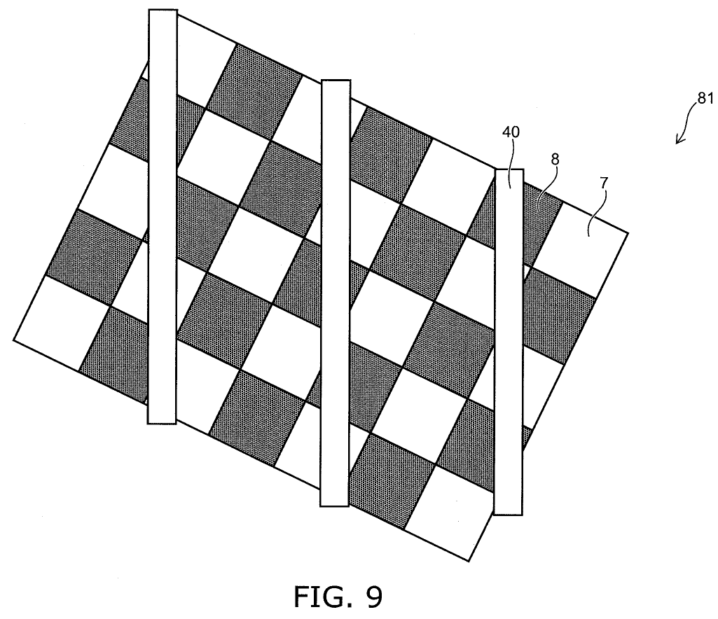

FIG. 9 is a plan view of a trench power MOS transistor with the N source layers and the P⁺ body layers rotated. As shown in FIG. 9, in the trench power MOS transistor 81, with respect to the trench gates 40 juxtaposed in a striped pattern, the N source layers 7 and the P⁺ body layers 8 formed in a staggered pattern are rotated.

Here, the sum of the width of the N source layer 7 and the width of the P⁺ body layer 8 in the direction perpendicular to the trench gate 40 is set smaller than the spacing between the trench gates 40.

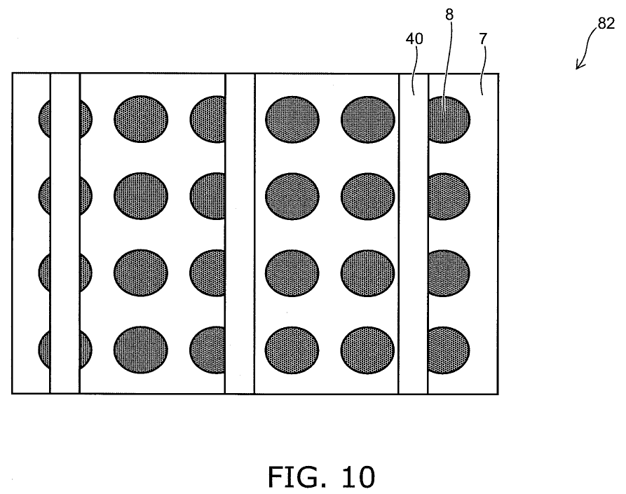

FIG. 10 is a plan view of a trench power MOS transistor with circular P⁺ body layers arranged therein. As shown in FIG. 10, in the trench power MOS transistor 82, a plurality of circular P⁺ body layers 8 are arranged horizontally at even intervals with respect to the trench gates 40 juxtaposed in a striped pattern. The circular P⁺ body layers 8 are formed with a pitch of the P⁺ body layer pitch Wbp, which is set smaller than the spacing between the trench gates 40. Here, although the P⁺ body layer 8 is circular, the P⁺ body layer 8 is not necessarily limited thereto. For instance, the P⁺ body layer 8 is shaped like a triangle, or n-gon (where n is 5 or more).

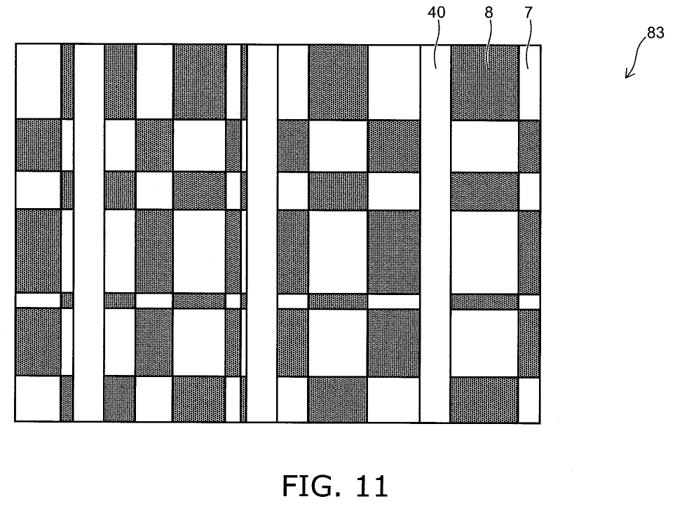

FIG. 11 is a plan view of a trench power MOS transistor with rectangular P⁺ body layers arranged therein with an irregular pitch. As shown in FIG. 11, in the trench power MOS transistor 83, N source layers 7 and P⁺ body layers 8 formed like irregular rectangles in a staggered pattern are provided horizontally with respect to the trench gates 40 juxtaposed in a striped pattern. The irregular pitch of the P⁺ body layers 8 is at least the P⁺ body layer pitch Wbp or less, and set smaller than the spacing between the trench gates 40.

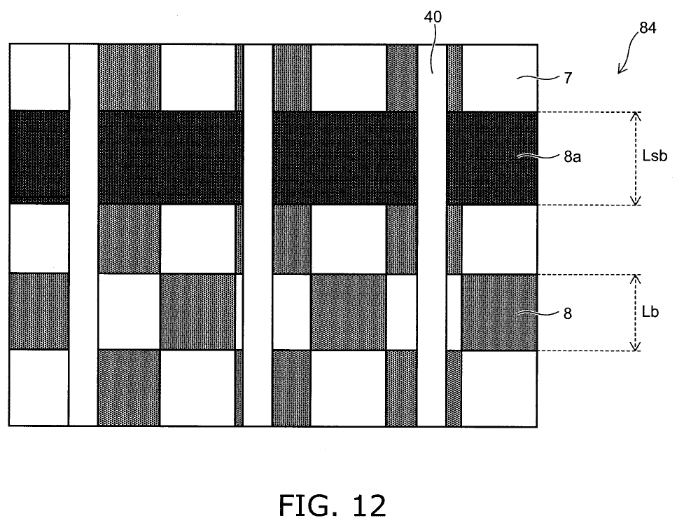

FIG. 12 is a plan view of a trench power MOS transistor with striped P⁺ body layers further added thereto. As shown in FIG. 12, in the trench power MOS transistor 84, N source layers 7 and P⁺ body layers 8 formed in a staggered pattern, and P⁺ body layers 8a arranged in a horizontally striped pattern are provided with respect to the trench gates 40 juxtaposed in a vertically striped pattern. The vertical P⁺ body layer dimension Lsb of the P⁺ body layer 8a is different from the vertical P⁺ body layer dimension Lb of the P⁺ body layer 8.

The trench power MOS transistor 84 with the P⁺ body layers 8 thus arranged therein can ensure the output breakdown voltage like the trench power MOS transistor 80 shown in FIG. 1. Furthermore, by controlling the P⁺ body layer dimension Lsb, the channel ratio of the ON state can be controlled, and the value of ON resistance can be controlled.

As described above, in the semiconductor device and the method for manufacturing the same of this embodiment, a plurality of trench gates 40 are juxtaposed in a striped pattern. N source layers 7 and P⁺ body layers 8 are arranged perpendicular to the trench gate 40 in a staggered pattern. The N source layers 7 and the P⁺ body layers 8 are divided by the trench gate 40, and are not provided immediately below the trench gate 40. The sum of the width of the N source layer 7 and the width of the P⁺ body layer 8 is smaller than the spacing between the trench gates 40. Trench grooves 4 are formed by RIE using a mask material 20 as a mask so as to penetrate through the P body layer 3 and expose the surface of the N drain layer 2. The trench groove 4 is filled with a gate insulating film 5 and a gate electrode film 6 constituting a trench gate. The N source layer 7 is formed by As (arsenic) ion implantation on the entire surface and high-temperature heat treatment. The P⁺ body layer 8 is formed by ion implantation using as a mask a resist film formed without using an alignment mark, and high-temperature heat treatment.

Thus, the operation of the parasitic npn bipolar transistor can be significantly suppressed. The output breakdown voltage can be ensured even if the trench power MOS transistor 80 is miniaturized. Furthermore, even if the features are miniaturized, there is no need to allow for the mask alignment margin. Hence, the miniaturization does not result in the yield decrease of the trench power MOS transistor 80.

In the foregoing, although this embodiment is applied to Nch trench power MOS transistors, this embodiment is also applicable to Pch trench power MOS transistors. Furthermore, although this embodiment is applied to silicon trench power MOS transistors, this embodiment is not necessarily limited thereto. This embodiment is also applicable to power devices based on SiC or GaN.

### Second Embodiment

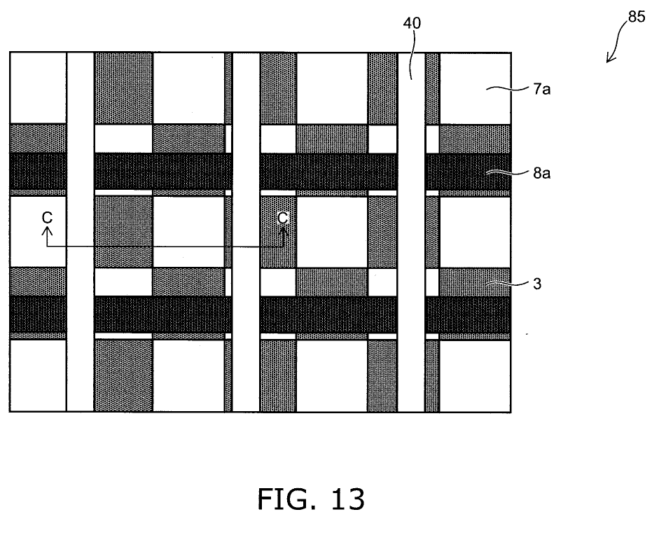

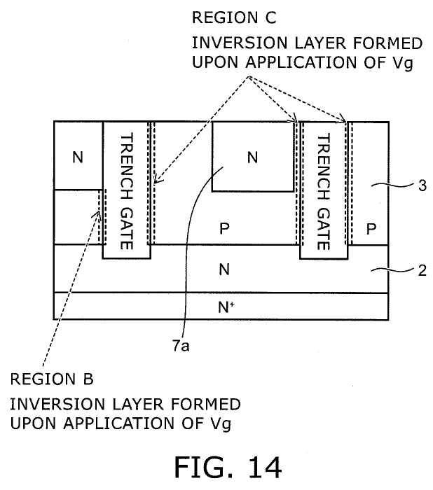

Next, a semiconductor device according to a second embodiment of the invention is described with reference to the drawings. FIG. 13 is a plan view showing a trench power MOS transistor. FIG. 14 shows formation of an inversion layer in the trench power MOS transistor taken along line C-C in FIG. 13. In this embodiment, N source layers are arranged in a staggered pattern, and striped P⁺ body layers are arranged perpendicular to the striped trench gates.

In the following, the same constituent portions as those in the first embodiment are labeled with like reference numerals, with the description thereof omitted, and only the different portions are described.

As shown in FIG. 13, the trench power MOS transistor 85 is a silicon Nch MOS transistor having a trench gate structure. The trench power MOS transistor 85 includes a plurality of trench gates 40 juxtaposed vertically in the figure. The trench power MOS transistor 85 includes an N⁺ silicon substrate and an N drain layer, although not shown, similar in structure to those in the first embodiment.

The N source layers 7a and the P body layers 3 are shaped like rectangles and arranged perpendicular to the trench gate 40 (horizontally in the figure) in a staggered pattern. The striped P⁺ body layers 8a are arranged perpendicular to the trench gate 40. The N source layers 7a and the P body layers 3 are arranged in a similar pattern to the N source layers 7 and the P⁺ body layers 8 in the first embodiment. That is, the sum of the width of the N source layer 7a and the width of the P body layer 3 is smaller than the spacing between the trench gates 40.

Here, the N source layer 7a is formed by ion implantation using a resist film as a mask and high-temperature heat treatment. This resist film is formed similarly to the initial exposure step (first exposure) without using an alignment mark. The P⁺ body layer 8a is formed by ion implantation using a resist film as a mask and high-temperature heat treatment. This resist film is formed similarly to the initial exposure step (first exposure) without using an alignment mark. The N source layers 7a and the P⁺ body layers 8a are divided by the trench gate 40, and are not provided immediately below the trench gate 40.

Here, although not shown, a P⁺ body layer 8 is provided at the outer edge of the P body layer 3 provided in the end portion of the trench power MOS transistor 85.

As shown in FIG. 14, the trench power MOS transistor 85 is turned on when the gate is applied with a gate voltage Vg. At this time, an inversion layer is formed in the channel region B immediately below the source layer 7a (in the P body layer 3 between the source layer 7a and the N drain layer 2 on the side surface of the trench gate 40). Simultaneously, an inversion layer is formed in the channel region C on the side surface of the trench gate 40 (in the P body layer 3 on the side surface of the trench gate 40).

In the trench power MOS transistor 85, as in the first embodiment, the operation of the parasitic npn bipolar transistor (where the N drain layer 2 is a collector, the P body layer 3 is a base, and the N source layer 7a is an emitter) can be significantly suppressed. Therefore, the decrease of output breakdown voltage (avalanche withstand capability) is suppressed, and a high output breakdown voltage (avalanche withstand capability) can be ensured. Furthermore, when the gate is applied with a gate voltage Vg, an inversion layer is formed also in the P body layer 3 on the side surface of the trench gate 40. This serves to achieve lower ON resistance than in the first embodiment. Here, by controlling the width of the P⁺ body layer 8a (vertical width in FIG. 13), the channel ratio of the ON state can be controlled. Hence, the ON resistance of the trench power MOS transistor 85 can be controlled arbitrarily.

In this example, the N source layers 7a of the trench power MOS transistor 85 are arranged in a staggered pattern, and the striped P⁺ body layers 8a are arranged perpendicular to the trench gate 40. However, the trench power MOS transistor may be configured differently.

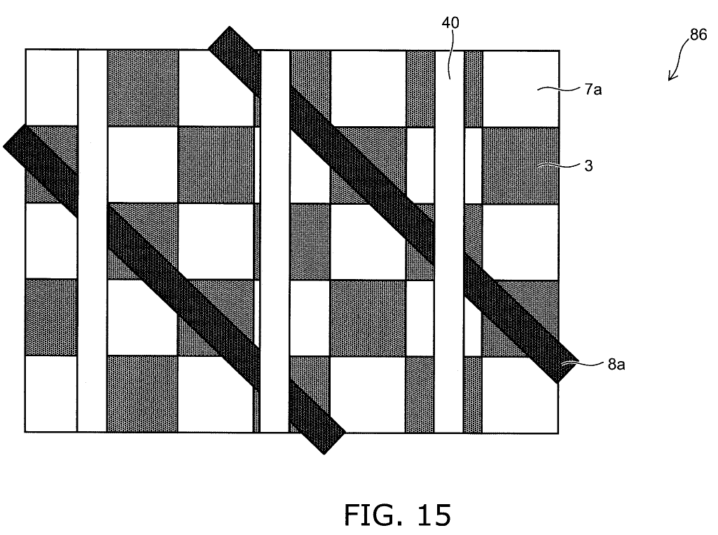

FIG. 15 is a plan view of a trench power MOS transistor with the P⁺ body layers rotated. As shown in FIG. 15, in the trench power MOS transistor 86, with respect to the trench gates 40 juxtaposed in a striped pattern, the N source layers 7a and the P body layers 3 formed in a staggered pattern are arranged horizontally, and the striped P⁺ body layers 8a are rotated.

As described above, in the semiconductor device of this embodiment, a plurality of trench gates 40 are juxtaposed in a striped pattern. N source layers 7a and P body layers 3 are arranged perpendicular to the trench gate 40 in a staggered pattern. P⁺ body layers 8a are arranged perpendicular to the trench gate 40 in a striped pattern. The N source layers 7a and the P⁺ body layers 8a are divided by the trench gate 40, and are not provided immediately below the trench gate 40. The sum of the width of the N source layer 7a and the width of the P body layer 3 is smaller than the spacing between the trench gates 40.

Thus, in addition to the effect of the first embodiment, when the gate is applied with a gate voltage Vg, an inversion layer is formed in the P body layer 3 on the side surface of the trench gate 40. This serves to achieve lower ON resistance than in the first embodiment. Here, by controlling the width of the P⁺ body layer 8, the channel ratio of the ON state can be controlled. Hence, the ON resistance of the trench power MOS transistor 85 can be controlled arbitrarily.

### Third Embodiment

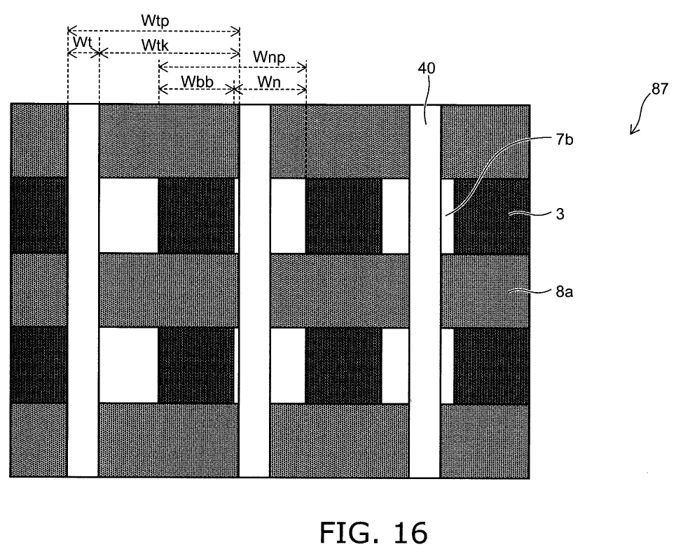

Next, a semiconductor device according to a third embodiment of the invention is described with reference to the drawings. FIG. 16 is a plan view showing a trench power MOS transistor. In this embodiment, striped N source layers are arranged parallel to the striped trench gates, and striped P⁺ body layers are arranged perpendicular to the striped trench gates.

In the following, the same constituent portions as those in the first embodiment are labeled with like reference numerals, with the description thereof omitted, and only the different portions are described.

As shown in FIG. 16, the trench power MOS transistor 87 is a silicon Nch MOS transistor having a trench gate structure. The trench power MOS transistor 87 includes a plurality of trench gates 40 juxtaposed vertically in the figure. The trench power MOS transistor 87 includes an N⁺ silicon substrate and an N drain layer, although not shown, similar in structure to those in the first embodiment.

The N source layers 7b are arranged in a striped pattern parallel to the striped trench gates 40. The P⁺ body layers 8a are arranged in a striped pattern perpendicular to the striped trench gate 40. The crossing portion of the N source layer 7b and the P⁺ body layer 8a constitutes a P⁺ body layer 8a, because the impurity concentration in the P⁺ body layer 8a is relatively high.

The N source layer 7b is formed by ion implantation using a resist film as a mask and high-temperature heat treatment. This resist film is formed similarly to the initial exposure step (first exposure) without using an alignment mark. The P⁺ body layer 8a is formed by ion implantation using a resist film as a mask and high-temperature heat treatment. This resist film is formed similarly to the initial exposure step (first exposure) without using an alignment mark. The N source layers 7b and the P⁺ body layers 8a are divided by the trench gate 40, and are not provided immediately below the trench gate 40.

A P body layer 3 is formed between the P⁺ body layers 8a provided above and below the P body layer 3, and between the N source layers 7b provided to the left and right of the P body layer 3. Furthermore, a P body layer 3 is formed between the P⁺ body layers 8a provided above and below the P body layer 3, and between the N source layer 7b and the trench gate 40 provided to the left and right of the P body layer 3. The N source layer 7b has a horizontal dimension of N source layer dimension Wn and a horizontal pitch of N source layer pitch Wnp. The P body layer 3 has a horizontal dimension of P body layer dimension Wbb.

Here, although not shown, a P⁺ body layer is provided at the outer edge of the P body layer 3 provided in the end portion of the trench power MOS transistor 87.

Here, the relationship among the N source layer pitch Wnp, the P body layer dimension Wbb, and the N source layer dimension Wn is set as follows.

Wnp=Wbb+Wn (3)

The relationship among the N source layer pitch Wnp, the trench spacing Wtk, and the trench pitch Wtp is set as follows.

Wnp<Wtk<Wtp (4)

Thus, by these settings, two types of regions occur between the trench gates 40 arranged horizontally. One type of region includes an N source layer 7, a P body layer 3, and an N source layer 7. The other type of region includes a P body layer 3, an N source layer 7, and a P body layer 3.

As described above, in the semiconductor device of this embodiment, a plurality of trench gates 40 are juxtaposed in a striped pattern. N source layers 7b are arranged parallel to the trench gates 40. P⁺ body layers 8a are arranged perpendicular to the trench gate 40 in a striped pattern. The N source layers 7b and the P⁺ body layers 8a are divided by the trench gate 40, and are not provided immediately below the trench gate 40. The sum of the width of the N source layer 7b and the width of the P body layer 3 is smaller than the spacing between the trench gates 40.

Thus, in addition to the effect of the first embodiment, when the gate is applied with a gate voltage Vg, an inversion layer is formed in the P body layer 3 on the side surface of the trench gate 40. This serves to achieve lower ON resistance than in the first embodiment.

The invention is not limited to the above embodiments, but may be variously modified without departing from the spirit of the invention.

In the foregoing, the embodiments are applied to trench power MOS transistors. However, the embodiments are also applicable to trench IGBTs (insulated gate bipolar transistors). Furthermore, in the foregoing, N source layers and P⁺ body layers are formed after trench gates are formed. However, alternatively, trench gates may be formed after N source layers and P⁺ body layers are formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A semiconductor device comprising:
a semiconductor substrate of a first conductivity type;
a drain layer of the first conductivity type provided on the semiconductor substrate and having an impurity concentration lower than an impurity concentration of the semiconductor substrate;
a first body layer of a second conductivity type provided on a surface of the drain layer;
a plurality of source layers of the first conductivity type discretely arranged on a surface of the first body layer in a staggered pattern with a first spacing in a first direction and a second spacing in a second direction orthogonal to the first direction, each of the source layers having a first width in the first direction and a second width in the second direction;
a plurality of trenches extending in a third direction on the surface of the first body layer, arranged in a fourth direction orthogonal to the third direction, and piercing through the source layer and the first body layer into the drain layer; and
a gate electrode buried in each of the trenches via a gate insulating film provided at bottom and on a side surface of the each of the trenches,
sum of the width of the source layer and the spacing between the source layer and the adjacent source layer being smaller than spacing between the adjacent trenches.

2. The device according to claim 1, wherein the first spacing and the first width, and the second spacing and the second width are irregularly varied in the first direction and the second direction, respectively.

3. The device according to claim 1, wherein the first spacing and the first width, and the second spacing and the second width are constant in the first direction and the second direction, respectively.

4. The device according to claim 3, wherein
second body layers of the second conductivity are further provided on the surface of the first body layer between the source layers contiguously to the source layers, the second body layers having an impurity concentration higher than an impurity concentration of the first body layer, the second body layers being arranged in a staggered pattern on the surface of the first body layers.

5. The device according to claim 4, wherein planar shape of each of the second body layer is a circle or an n-gon (n≧3).

6. The device according to claim 4, further comprising:
a third body layer of the second conductivity type having an impurity concentration higher than an impurity concentration of the first body layer and extending in the fourth direction, the trench piercing through the third body layer.

7. The device according to claim 4, wherein the first direction and the third direction are not parallel.

8. The device according to claim 4, wherein the first direction and the third direction are parallel, and sum of the second spacing of the source layer and the second width of the source layer is smaller than the spacing between the trenches adjacent in the fourth direction.

9. The device according to claim 3, further comprising:
a second body layer of the second conductivity type having an impurity concentration higher than an impurity concentration of the first body layer and extending in the fourth direction, the trench piercing through the second body layer, the surface of the first body layer being exposed between the source layers arranged in the staggered pattern.

10. The device according to claim 9, wherein the first direction and the third direction are not parallel.

11. The device according to claim 9, wherein the first direction and the third direction are parallel, and sum of the second spacing of the source layer and the second width of the source layer is smaller than the spacing between the trenches adjacent in the fourth direction.

12. The device according to claim 3, further comprising:
a second body layer of the second conductivity type having an impurity concentration higher than an impurity concentration of the first body layer and extending in a direction slanted from the fourth direction, the trench piercing through the second body layer, the surface of the first body layer being exposed between the source layers arranged in the staggered pattern.

13. A semiconductor device comprising:
a semiconductor substrate of a first conductivity type;
a drain layer of the first conductivity type provided on the semiconductor substrate and having an impurity concentration lower than an impurity concentration of the semiconductor substrate;
a first body layer of a second conductivity type provided on a surface of the drain layer;
a source layer of the first conductivity type provided on a surface of the first body layer;
a second body layer of the second conductivity type provided on the surface of the first body layer, crossing the source layer, and having an impurity concentration higher than an impurity concentration of the first body layer and the source layer;
a trench piercing through the second body layer or the source layer, further piercing the first body layer, and provided so that the surface of the drain layer is exposed; and
a trench gate provided so as to fill the trench, the trench gate being composed of a gate insulating film and a gate electrode film provided on the gate insulating film, the gate insulating film being provided at bottom and on a side surface of the trench,
the source layer being arranged parallel to the trench gate in plan view, the second body layer being arranged perpendicular to the trench gate in plan view, and pitch of the source layers as viewed perpendicular to the trench gate being smaller than spacing between the trench gates.

14. A method for manufacturing a semiconductor device, comprising:
forming a drain layer of a first conductivity type on a semiconductor substrate of the first conductivity type, the drain layer having an impurity concentration lower than an impurity concentration of the semiconductor substrate;
forming a first body layer of a second conductivity type on a surface of the drain layer;
forming a trench piercing through the first body layer, the trench exposing the surface of the drain layer;
forming a trench gate so as to fill the trench, the trench gate being composed of a gate insulating film and a gate electrode film provided on the gate insulating film, the gate insulating film being provided at bottom and on a side surface of the trench;
ion-implanting impurity ions of the first conductivity type into an entire surface of the first body layer and a surface of the trench gate;
forming a resist film on the first body layer and the surface of the trench gate, the resist film having a pitch smaller than spacing between the trench gates;
ion-implanting impurity ions of the second conductivity type into the first body layer and the surface of the trench gate using the resist film as a mask; and
forming a second body layer of the second conductivity type on the surface of the first body layer by performing high-temperature heat treatment to activate an ion-implanted layer after removing the resist film, the second body layer having an impurity concentration higher than an impurity concentration of a source layer of the first conductivity type and the first body layer.

15. The method according to claim 14, wherein lithography is performed without using an alignment mark in the forming the resist film.

16. The method according to claim 14, wherein the resist film is formed in a staggered pattern in the forming the resist film, with the resist being repetitively and discretely arranged in a first direction and a second direction orthogonal to the first direction.

17. The method according to claim 16, wherein the first direction is parallel to extending direction of the trench.

18. The method according to claim 16, wherein the first direction crosses extending direction of the trench.
